(19) United States
(12) Patent Application Publication
(10) Pub. No.: US 2023/0317571 A1
(43) Pub. Date: Oct. 5, 2023

(54) LEAD FINGER WITH Z-DIRECTION OBSTRUCTION FEATURE

(71) Applicant: Texas Instruments Incorporated, Dallas, TX (US)

(72) Inventors: Hsiang Ming Hsiao, Taipei City (TW); Hung-Yu Chou, Taipei City (TW); Yuh-Harng Chien, New Taipei City (TW); Chih-Chien Ho, New Taipei City (TW); Che Wei Tu, Changhua City (TW); Bo-Hsun Pan, New Taipei City (TW); Megan Chang, New Taipei City (TW)

(21) Appl. No.: 17/708,038

(22) Filed: Mar. 30, 2022

(51) Int. Cl. H01L 23/495; H01L 23/31; H01L 21/48; H01L 21/56

(52) U.S. Cl. CPC H01L 23/49555; H01L 21/56; H01L 21/4821; H01L 23/3107

(57) ABSTRACT

An electronic device with a conductive lead having an internal first section and an external second section extending outside a molded package structure, the first section having an obstruction feature extending vertically from a top or bottom side of the conductive lead and engaging a portion of the package structure to oppose movement of the conductive lead outward from the package structure.

### BACKGROUND

The evolution of fine pitch electronic device packages reduces the lateral spacing between adjacent leads and reduces the room for mushroom head internal lead ends. In addition, the continued reduction in size of packaged electronic devices can reduce the lateral spacing between conductive lead ends and die pads to which semiconductor dies are mounted in the interior of the package structure. Increasing the size and/or number of die pads to accommodate high voltage isolated multichip modules reduces the area available for mold lock features on leads. Reduced lateral extent of the internal lead ends of the leads increases the risk of the lead moving outward from the package side when exposed to mechanical force, sometimes referred to as lead pull out. Lead pull out can result in damage or even disconnection of a wire lead stich bond from the lead finger. Laterally extending features, such as so-called mushroom head structures, can be incorporated into the lead fingers within the molded package material to mitigate lead pull out. However, the continued decrease in lead pitch spacing for ever-finer pitch device designs reduces the size and effectiveness of laterally extending features.

### SUMMARY

In one aspect, an electronic device includes a package structure and a conductive lead. The package structure has a first side, a second side, a bottom side, and a top side. The first and second sides are spaced apart from one another along a first direction and extend along a second direction that is orthogonal to the first direction, and the bottom and top sides are spaced apart from one another along a third direction that is orthogonal to the first and second directions. The conductive lead has a first section enclosed by the package structure and extending along the first direction into the package structure from the first side to an end. The first section has opposite first and second portion sides and an obstruction feature. The first and second portion sides are spaced apart from one another along the third direction, and the obstruction feature extends from one of the first and second portion sides along the third direction and engages a portion of the package structure to oppose movement of the conductive lead outward from the first side along the first direction.

In another aspect, a lead frame includes a conductive lead having a first section and a second section. The first section extends along a first direction in a plane of the first direction and an orthogonal second direction and has opposite first and second portion sides and an obstruction feature. The first and second portion sides are spaced apart from one another along a third direction that is orthogonal to the first and second directions, and the obstruction feature extends from one of the first and second portion sides along the third direction to engage a portion of a package structure to oppose movement of the conductive lead relative to the package structure along the first direction.

In a further aspect, a method of fabricating an electronic device includes forming a lead frame with conductive leads in a plane of orthogonal first and second directions, forming an indent or raised feature extending from a side of one of the conductive lead to provide an obstruction feature, attaching a die to the lead frame, electrically coupling conductive terminals of the die to respective ones of the conductive leads, and performing a molding process that forms a package structure that encloses a portion of the one of the conductive leads and engages the obstruction feature to oppose movement of the one of the conductive leads relative to the package structure along the first direction.

### BRIEF DESCRIPTION OF THE DRAWINGS

FIG. 1 is a perspective view of a packaged electronic device with conductive leads having vertical obstruction features to mitigate lead pull out.

FIG. 1A is a partial perspective side view of one conductive lead in the packaged electronic device of FIG. 1.

FIG. 1B is a perspective bottom view of the conductive lead of FIG. 1A.

FIG. 2 is a partial perspective view of another conductive lead example with vertical indent obstruction features to mitigate lead pull out in another packaged electronic device.

FIG. 2A is a perspective bottom view of the conductive lead of FIG. 2.

FIG. 3 is a partial perspective view of another conductive lead example with vertical indent obstruction features to mitigate lead pull out in another packaged electronic device.

FIG. 3A is a perspective bottom view of the conductive lead of FIG. 3.

FIG. 4 is a partial bottom perspective view of another packaged electronic device with a conductive lead having vertical obstruction features to mitigate lead pull out.

FIG. 4A is a perspective bottom view of the conductive lead of FIG. 4.

FIG. 5 is a partial bottom perspective view of another packaged electronic device with a conductive lead having vertical obstruction features to mitigate lead pull out.

FIG. 5A is a perspective bottom view of the conductive lead of FIG. 5.

FIG. 6 is a flow diagram of a method of fabricating a packaged electronic device.

FIG. 7 is a partial side elevation view of the conductive lead example of FIGS. 2 and 2A undergoing a chemical etch process to create an indented obstruction feature in a first section of the conductive lead.

FIG. 7A is a partial bottom plan view of the conductive lead of FIG. 7.

FIG. 7B is a partial bottom plan view of a lead frame including the conductive lead of FIGS. 7 and 7A.

FIG. 8 is a partial side elevation view of another conductive lead example undergoing a punch process in a prospective bend area in a first section of the conductive lead.

FIG. 8A is a partial bottom plan view of the conductive lead of FIG. 8 with three prospective bend areas.

FIG. 8B is a partial side elevation view of the conductive lead of FIGS. 8 and 8A undergoing a bending process to form vertical obstruction features.

FIG. 8C is a partial bottom plan view of the conductive lead of FIG. 8-8B with three vertical obstruction features.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections.

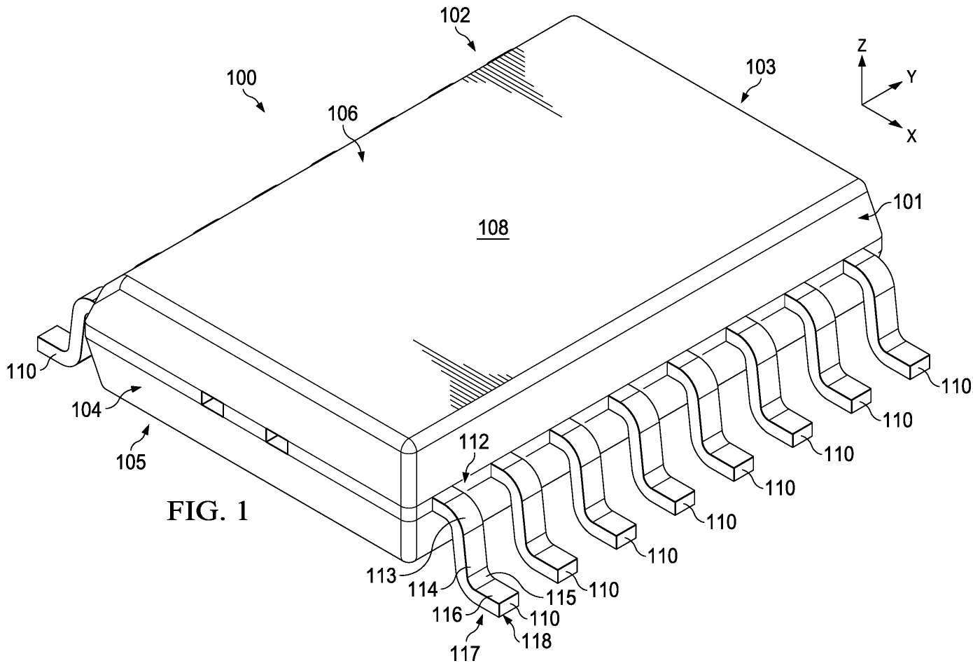

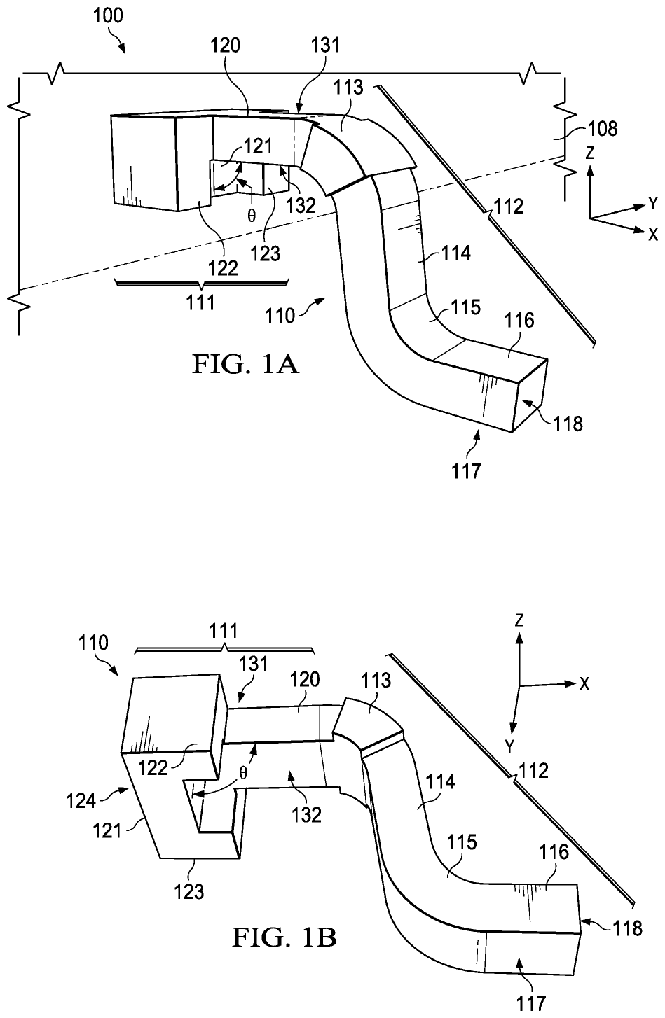

Referring initially to FIGS. 1-1B, FIG. 1 shows a perspective view of a packaged electronic device 100 illustrated in an example position in a three-dimensional space with respective first, second, and third mutually orthogonal directions X, Y, and Z. As best shown in FIG. 1, the packaged electronic device 100 includes opposite first and second sides 101 and 102 that extend along the second direction Y and are spaced apart from one another along the first direction X, as well as respective third and fourth sides 103 and 104 spaced apart from one another along the second direction Y, a bottom side 105, and a top side 106 spaced apart from the bottom side 105 along the third direction Z. In the illustrated example, the bottom and top sides 105 and 106 are generally planar and extend in respective X-Y planes, and the sides 101-104 each have tapered surfaces created by corresponding tapered walls of a mold cavity during molding to form a molded package structure 108. In other examples, one or more of the sides can have different surface profiles, including planar and/or non-planar shapes.

The packaged electronic device 100 includes conductive leads 110 that extend out of the first and second sides 101 and 102. In the illustrated example, the conductive leads 110 are gullwing leads that extend outward along the first direction X from the respective side 101, 102, and then extend downward generally along the third direction Z, and then outward along the first direction X to form feet structures for soldering to a host printed circuit board (PCB, not shown). In another implementation, the conductive leads 110 can have different shapes and forms, such as J-type leads that extend outward along the first direction X, then downward along the third direction Z, and then inward.

As further shown in FIGS. 1A and 1B, the conductive leads 110 have vertical obstruction portions 121, 122, and 123 with obstruction features that engage with respective portions of the molded material of the package structure 108, in order to oppose movement of the conductive lead 110 outward from the respective sides 101, 102 along the first direction X. The individual conductive leads 110 have a first section 111 enclosed by the package structure 108 and a second section 112 that extends outside the first side 101 of the package structure 108. The following description relates to the structure of the conductive leads 110 along the first side 101 of the packaged electronic device 100, and the conductive leads 110 along the second side 102 have similar structures.

The external second section 112 of the conductive lead 110 has a first portion 113, a second portion 114, a third portion 115, and a fourth portion 116 with a bottom side 117 for soldering to a conductive PCB pad (not shown), and an end 118. The first portion 113 extends along the first direction X away from the first side 101 and is bent or formed so as to curve downward away from the top side 106. The second portion 114 extends downward generally along the third direction Z from the first portion 113 to the third portion 115, which is bent or otherwise formed outward away from the first side 101 along the first direction X. The fourth portion 116 extends generally along the first direction X from the third portion 115 to the end 118.

The first section 111 has a base portion 120 and obstruction portions 121, 122, and 123. The base portion 120 extends along the first direction X into the package structure 108 from the first side 101 to an interior end 124. The first section 111 has opposite first and second (e.g., upper and lower) portion sides 131 and 132 that are spaced apart from one another along the third direction Z. The obstruction portions 121, 122, and 123 have vertical sidewalls that form obstruction features that extend from the second portion side 132 downward along the third direction Z. The sidewall obstruction features of the obstruction portions 121, 122, and 123 engage respective portions of the molded package structure 108 to oppose movement of the conductive lead 110 outward from the first side 101 along the first direction X. In the example of FIGS. 1-1B, the obstruction portions 121, 122, and 123 are conductive material (e.g., copper, aluminum, etc.) formed as part of the conductive lead 110 and form a U-shape with side wall obstruction features that extend outward from the second portion side 132 toward the bottom side 105 of the package structure 108 at a non-zero angle θ from the second portion side 132. In this example, the non-zero angle θ is approximately 90 degrees.

In other examples (not shown), the conductive lead 110 has one or more obstruction features that extend from the upper or first portion side 131 upward along the third direction Z and engage respective portions of the molded package structure 108. However, the downward extension of the illustrated obstruction portions 121, 122, and 123 from the second portion side 132 downward leaves more room on the upper or first portion side 131 to facilitate bond wire connection to the upper or first portion side 131 of the interior first section 111 of the conductive lead 110. Moreover, the extension of the obstruction portions 121, 122, and 123 approximately along the third direction Z facilitates reduced lateral spacing of adjacent leads along the second direction Y to enable finer pitch spacing device packaging solutions. Moreover, the extension of the obstruction portions 121, 122, and 123 approximately along the third direction Z allows larger and/or more interior die attach pads to accommodate high voltage isolated multichip module and other packaged electronic device configurations. In one example, the elevated obstruction portions 121, 122, and 123 are formed as the initial thickness of a manufactured lead frame panel, and the remaining portions of the lead frame are chemically etched prior to die attach and wirebonding to leave the elevated obstruction features of the obstruction portions 121, 122, and 123.

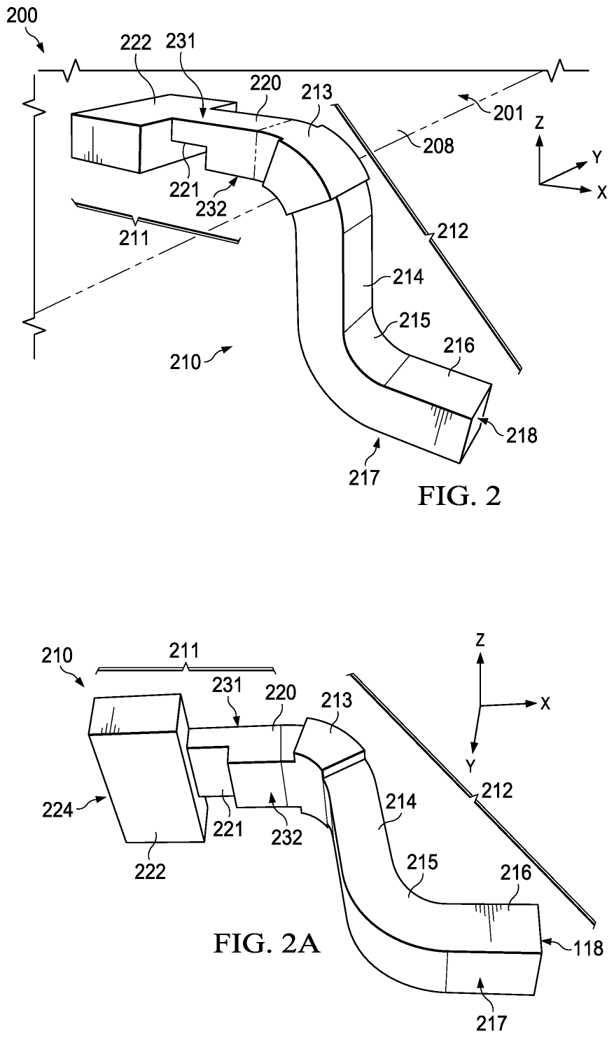

Referring now to FIGS. 2 and 2A, FIG. 2 shows a partial perspective view of another packaged electronic device 200 that includes conductive leads 210 with vertical indent obstruction features to mitigate lead pull out and FIG. 2A shows a perspective bottom view of the conductive lead 210. FIG. 2 shows a perspective view of a portion of the packaged electronic device 200 in an example position in a three-dimensional space with respective orthogonal first, second, and third orthogonal directions X, Y, and Z, and the packaged electronic device 200 includes a first side 201 with a conductive lead 210, and a bottom side 205, as well as an opposite second side, third and fourth sides and a top side (not shown in FIG. 2). The first side 201 extends along the second direction Y. The packaged electronic device 200 in one example includes gullwing or other type conductive leads 210 that extend out of the first and second sides, similar to the configuration shown in FIG. 1 above.

As further shown in FIG. 2, the conductive lead 210 has an indent 221 that provides a side wall obstruction feature that engages with an associated portion of the molded material of the package structure 208 to oppose movement of the conductive lead 210 outward from the first side 201 along the first direction X. The conductive lead 210 has a first section 211 enclosed by the package structure 208 and a second section 212 that extends outside the first side 201 of the package structure 208. The external second section 212 of the gullwing conductive lead 210 has a first portion 213, a second portion 214, a third portion 215, and a fourth portion 216 with a bottom side 217 for soldering to a conductive PCB pad (not shown), and an end 218. The first portion 213 extends along the first direction X away from the first side 201 and is bent or otherwise formed so as to curve downward away from the top side 206. The second portion 214 extends downward generally along the third direction Z from the first portion 213 to the third portion 215, which is bent or otherwise formed outward away from the first side 201 along the first direction X. The fourth portion 216 extends generally along the first direction X from the third portion 215 to the end 218.

The first section 211 of the conductive lead 210 has a base portion 220 and an indent 221 and an obstruction portion 222. The base portion 220 extends along the first direction X into the package structure 208 from the first side 201 to an interior end 224. The first section 211 has opposite first and second (e.g., upper and lower) portion sides 231 and 232 that are spaced apart from one another along the third direction Z. The indent 221 and obstruction portion 222 form side wall obstruction features that extend from the second portion side 232 downward along the third direction Z and engage respective portions of the molded package structure 208 to oppose movement of the conductive lead 210 outward from the first side 201 along the first direction X. In the example of FIGS. 2 and 2A, the obstruction feature 222 is conductive material (e.g., copper, aluminum, etc.) formed as part of the conductive lead 210, and include the indent 221 that includes or provides an obstruction feature, where the indent 221 extends into the second portion side 232 toward the first portion side 231 of the first section 211 along the third direction Z. In the example of FIGS. 2 and 2A, the indent 221 extends laterally through opposite respective sides of the base portion 220 along the second direction Y. The indent 221 in one example extends approximately 50% into the second portion side 232 toward the first portion side 231 of the first section 211.

In other examples (not shown), the conductive lead 210 has an indent or other obstruction features that extend from the upper or first portion side 231 downward along the third direction Z and engage respective portions of the molded package structure 208. However, the upward extension of the illustrated obstruction features of the indent 221 from the second portion side 232 leaves more room on the upper or first portion side 231 to facilitate bond wire connection to the upper or first portion side 231 of the interior first portion 211 of the conductive lead 210. The extension of the side wall obstruction features approximately along the third direction Z facilitates reduced lateral spacing of adjacent leads along the second direction Y to enable finer pitch spacing device packaging solutions. Moreover, the extension of the indent 221 and the obstruction portion 222 approximately along the third direction Z allows larger and/or more interior die attach pads to accommodate high voltage isolated multichip module and other packaged electronic device configurations. In one example, the indent 221 is formed by chemical etching or cutting or die punching into the initial thickness of a manufactured lead frame panel.

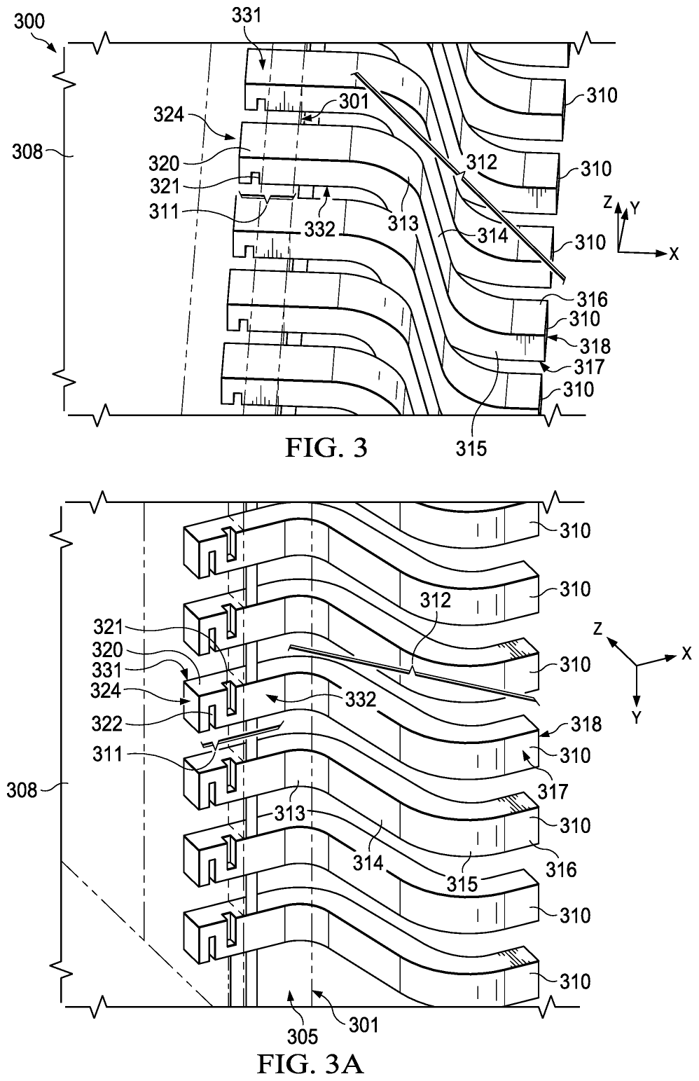

Referring now to FIGS. 3 and 3A, FIG. 3 shows a partial perspective view of another packaged electronic device 300 that includes conductive leads 310 with vertical indent obstruction features to mitigate lead pull out and FIG. 3A shows a perspective bottom view of the conductive lead 310. FIGS. 3 and 3A show a portion of the packaged electronic device 300 in an example position in a three-dimensional space with respective orthogonal first, second, and third orthogonal directions X, Y, and Z, and the packaged electronic device 300 includes a first side 301 with a conductive lead 310, and a bottom side 305, as well as an opposite second side, third and fourth sides and a top side (not shown in FIG. 3). The first side 301 extends along the second direction Y. The packaged electronic device 300 in one example includes gullwing or other type conductive leads 310 that extend out of the first and second sides, similar to the configuration shown in FIG. 1 above.

The conductive lead 310 in this example has an indented vertical obstruction portions 321 and 322 that provide sidewall obstruction features that engage with associated portions of the molded material of the package structure 308 to oppose movement of the conductive lead 310 outward from the first side 301 along the first direction X. The conductive lead 310 has a first section 311 enclosed by the package structure 308 and a second section 312 that extends outside the first side 301 of the package structure 308. The external second section 312 of the gullwing conductive lead 310 has a first portion 313, a second portion 314, a third portion 315, and a fourth portion 316 with a bottom side 317 for soldering to a conductive PCB pad (not shown), and an end 318. The first portion 313 extends along the first direction X away from the first side 301 and is bent or otherwise formed so as to curve downward away from the top side 306. The second portion 314 extends downward generally along the third direction Z from the first portion 313 to the third portion 315, which is bent or otherwise formed outward away from the first side 301 along the first direction X. The fourth portion 316 extends generally along the first direction X from the third portion 315 to the end 318.

The first section 311 of the conductive lead 110 has a base portion 320 and respective first and second indents 321 and 322. The base portion 320 extends along the first direction X into the package structure 308 from the first side 301 to an interior end 324. The first section 311 has opposite first and second (e.g., upper and lower) portion sides 331 and 332 that are spaced apart from one another along the third direction Z. The indents 321 and 322 provide sidewalls that extend approximately along the third direction Z. The first indent 321 extends into the second portion side 332 toward the first portion side 331 of the first section 311, and the first indent 321 extends laterally through a first side of the base portion 320 toward an opposite second side of the base portion 320 along the second direction Y. The second indent 322 extends into the second portion side 332 toward the first portion side 331 of the first section 311, and the second indent 322 extends laterally through the second side of the base portion 320 toward the first side of the base portion 320 along the second direction Y. In this example, one indent extends through each lateral side of the base portion 320 from opposite sides. In another implementation, a third or further indents can be included (not shown) that extends into the second portion side 332 toward the first portion side 331 of the first section 311. The indents 321 and 322 in one example extend approximately 50% into the second portion side 332 toward the first portion side 331 of the first section 311 and are formed by chemical etching. The indents 321 and 322 form side wall obstruction features that extend from the second portion side 332 downward along the third direction Z and engage respective portions of the molded package structure 308 to oppose movement of the conductive lead 310 outward from the first side 301 along the first direction X.

In other examples (not shown), the conductive lead 310 has an indent or other obstruction features that extend from the upper or first portion side 331 downward along the third direction Z and engage respective portions of the molded package structure 308. However, the upward extension of the illustrated obstruction features of the indents 321 and 322 from the second portion side 332 leaves more room on the upper or first portion side 331 to facilitate bond wire connection to the upper or first portion side 331 of the interior first portion 311 of the conductive lead 310. The extension of the side wall obstruction features approximately along the third direction Z facilitates reduced lateral spacing of adjacent leads along the second direction Y to enable finer pitch spacing device packaging solutions. Moreover, the extension of the obstruction features of the indents 321 and 322 approximately along the third direction Z allows larger and/or more interior die attach pads to accommodate high voltage isolated multichip module and other packaged electronic device configurations. In one example, the indents 321 and 322 are formed by chemical etching or cutting or die punching into the initial thickness of a manufactured lead frame panel.

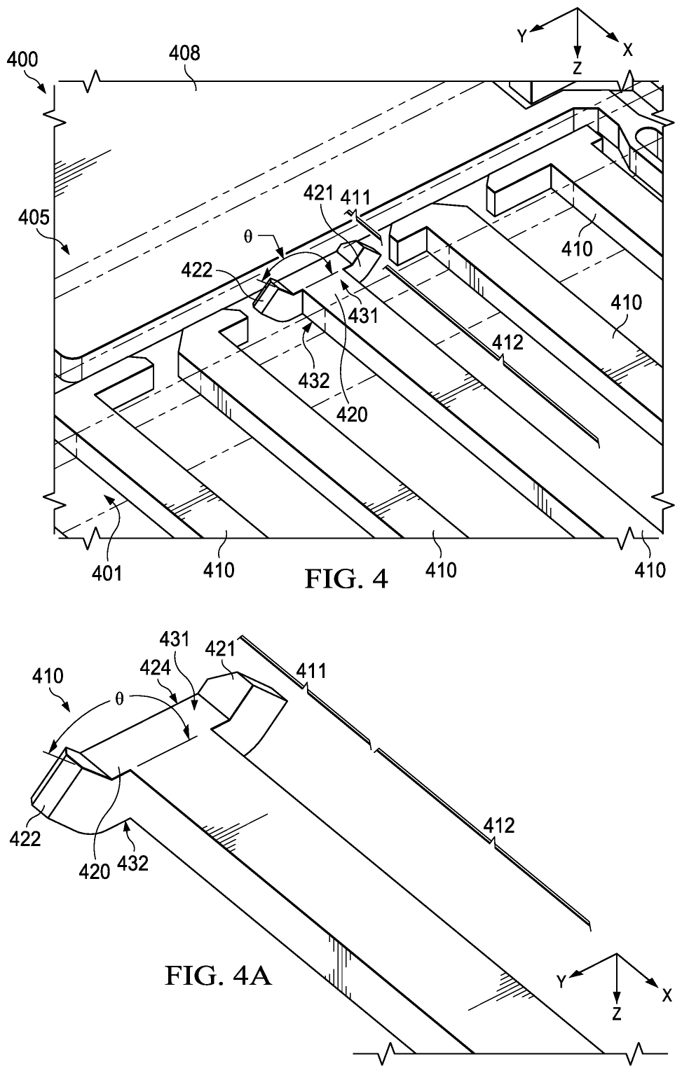

Referring now to FIGS. 4 and 4A, FIG. 4 shows a partial bottom perspective view of another packaged electronic device 400 with a conductive lead 410 having vertical obstruction features to mitigate lead pull out and FIG. 4A shows a perspective bottom view of the conductive lead 410. FIGS. 4 and 4A show a portion of the packaged electronic device 400 in an example position in a three-dimensional space with respective orthogonal first, second, and third orthogonal directions X, Y, and Z, and the packaged electronic device 400 includes a first side 401 with a conductive lead 410, and a bottom side 405, as well as an opposite second side, third and fourth sides and a top side (not shown in FIG. 4). The first side 401 extends along the second direction Y. The packaged electronic device 400 in one example includes gullwing or other type conductive leads 410 that extend out of the first and second sides, similar to the configuration shown in FIG. 1 above. In this example, the leads 410 shown in FIGS. 4 and 4A are illustrated prior to lead trim and form operations, and these can be subsequently formed into gullwing shaped leads, J-shaped leads, or other lead shapes (not shown).

The individual conductive leads 410 have a first section 411 enclosed by the package structure 408 and a second section 412 that extends outside the first side 401 of the package structure 408. The following description relates to the structure of the conductive leads 410 along the first side 401 of the packaged electronic device 400, and the conductive leads 410 along the second side have similar structures. The first section 411 of the conductive leads 410 in this example has a base portion 420 and respective first and second obstruction portions 421 and 422. The first and second obstruction portions 421 and 422 extend out of opposite respective sides of the base portion 420 along the second direction Y. The base portion 420 extends along the first direction X into the package structure 408 from the first side 401 to an interior end 424 (FIG. 4A). The first section 411 has opposite first and second (e.g., upper and lower) portion sides 431 and 432 that are spaced apart from one another along the third direction Z. In this example, the first and second obstruction portions 421 and 422 extend outward from the second portion side 432 toward the bottom side 105 of the package structure 108 at the non-zero angle θ from the second portion side 432. In one implementation, the non-zero angle θ is approximately 45 degrees. The example obstruction portions 421 and 422 form an angled anchor shape with vertical sidewalls that form obstruction features that extend from the second portion side 432 downward along the third direction Z. The sidewall obstruction features of the obstruction portions 421 and 422 engage respective portions of the molded package structure 408 to oppose movement of the conductive lead 410 outward from the first side 401 along the first direction X. The obstruction portions 421 and 422 are conductive material (e.g., copper, aluminum, etc.) formed as part of the conductive lead 410.

In other examples (not shown), the conductive lead 410 has one or more obstruction features that extend from the upper or first portion side 431 upward along the third direction Z and engage respective portions of the molded package structure 408. However, the downward extension of the illustrated obstruction portions 421 and 422 from the second portion side 432 leaves more room on the upper or first portion side 431 to facilitate bond wire connection to the upper or first portion side 431 of the interior first portion 411 of the conductive lead 410. Moreover, the extension of the obstruction portions 421 and 422 approximately along the third direction Z facilitates reduced lateral spacing of adjacent leads along the second direction Y to enable finer pitch spacing device packaging solutions. Moreover, the extension of the obstruction portions 421 and 422 approximately along the third direction Z allows larger and/or more interior die attach pads to accommodate high voltage isolated multichip module and other packaged electronic device configurations. In one example, the elevated obstruction portions 421 and 422 are formed by bending initially flat portions of a lead frame panel or strip during lead frame fabrication.

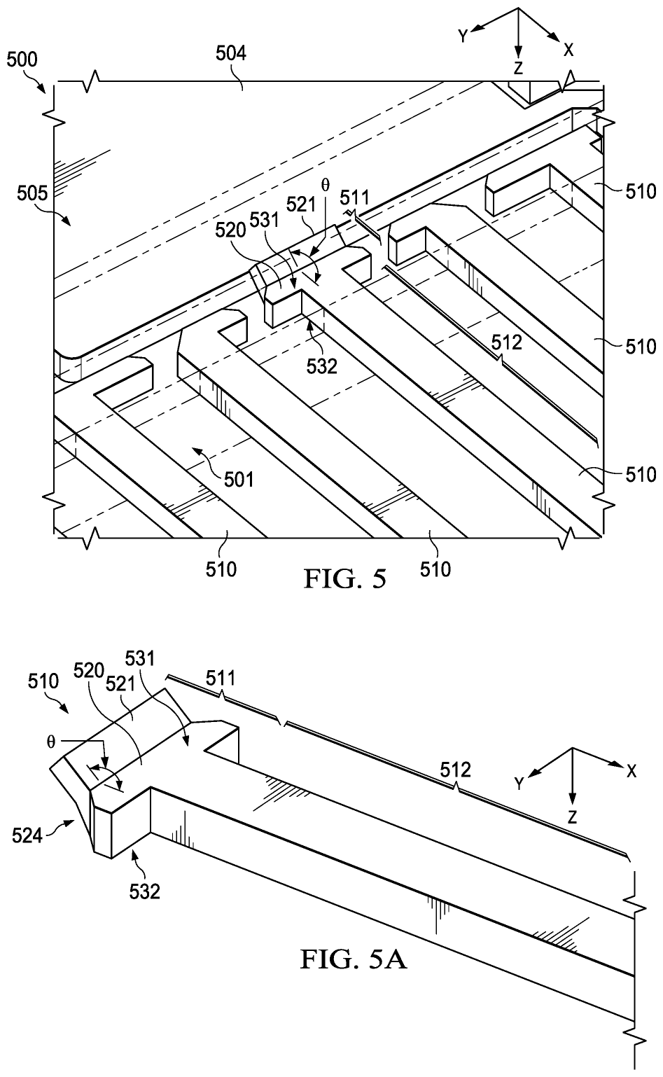

Referring now to FIGS. 5 and 5A, FIG. 5 shows a partial bottom perspective view of another packaged electronic device 500 with a conductive lead 510 having vertical obstruction features to mitigate lead pull out and FIG. 5A shows a perspective bottom view of the conductive lead 510. The packaged electronic device 500 is shown in an example position in a three-dimensional space with respective orthogonal first, second, and third orthogonal directions X, Y, and Z, and the packaged electronic device 500 includes a first side 501 with a conductive lead 510, and a bottom side 505, as well as an opposite second side, third and fourth sides and a top side (not shown in FIG. 5). The first side 501 extends along the second direction Y. The packaged electronic device 500 in one example includes gullwing or other type conductive leads 510 that extend out of the first and second sides, similar to the configuration shown in FIG. 1 above. In this example, the leads 510 shown in FIGS. 5 and 5A are illustrated prior to lead trim and form operations, and these can be subsequently formed into gullwing shaped leads, J-shaped leads, or other lead shapes (not shown). The individual conductive leads 510 have a first section 511 enclosed by the package structure 508 and a second section 512 that extends outside the first side 501 of the package structure 508. The following description relates to the structure of the conductive leads 510 along the first side 501 of the packaged electronic device 500, and the conductive leads 510 along the second side have similar structures.

The first section 511 of the conductive leads 510 has a base portion 520 an obstruction portion 521. The obstruction portion 521 extends out of the base portion 520 at an angle along the first direction X. The base portion 520 extends along the first direction X into the package structure 508 from the first side 501 to an interior end 524 (FIG. 5A). The first section 511 has opposite first and second (e.g., upper and lower) portion sides 531 and 532 that are spaced apart from one another along the third direction Z. The obstruction portion 521 extends outward from the second portion side 532 toward the bottom side 505 of the package structure 508 at the non-zero angle θ from the second portion side 532. In one implementation, the non-zero angle θ is approximately 45 degrees. The obstruction portion 521 extends outward from the second portion side 532 and partially toward the second side 502 of the package structure 508 along the first direction X. The obstruction portion 521 in this example also includes laterally disposed T-shaped features, for example, similar to mushroom head mold lock features. In other implementations, the laterally disposed features of the obstruction portion 521 can be omitted. The partially downward extension of the obstruction portion 521 engages a portion of the molded package structure 508 to oppose movement of the conductive lead 510 outward from the first side 501 along the first direction X. The obstruction portion 521 is conductive material (e.g., copper, aluminum, etc.) formed as part of the conductive lead 510.

In other examples (not shown), the conductive lead 510 has one or more obstruction features that extend from the upper or first portion side 531 upward along the third direction Z and engage respective portions of the molded package structure 508. However, the downward extension of the illustrated obstruction portion 521 from the second portion side 532 leaves more room on the upper or first portion side 531 to facilitate bond wire connection to the upper or first portion side 531 of the interior first portion 511 of the conductive lead 510. Moreover, the extension of the obstruction portion 521 at least partially along the third direction Z facilitates reduced lateral spacing of adjacent leads along the second direction Y to enable finer pitch spacing device packaging solutions. Moreover, the extension of the obstruction portion 521 partially along the third direction Z allows larger and/or more interior die attach pads to accommodate high voltage isolated multichip module and other packaged electronic device configurations. In one example, the obstruction portion 521 is formed by bending initially flat portions of a lead frame panel or strip during lead frame fabrication.

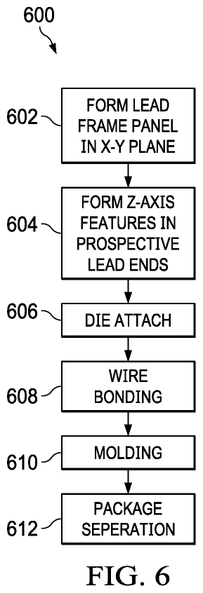

FIG. 6 shows a method 600 of fabricating a packaged electronic device. The method 600 includes forming a lead frame panel or strip at 602 that extends in a plane of orthogonal first and second directions (e.g., an X-Y plane). The lead frame formation at 602 includes providing the lead frame with conductive leads in the plane of the orthogonal first and second directions X and Y. At 604, the method 600 includes forming an indent or raised obstruction portion that extends from a side of one of the conductive leads to provide an obstruction feature (e.g., Z-axis features in the perspective lead ends). The method 600 also includes attaching a die (not shown) to the lead frame at 606, and electrically coupling conductive terminals of the die to respective ones of the conductive leads at 608. In one example, the electrical coupling at 608 includes performing a wire bonding process (not shown). In this or another example, the electrical coupling at 608 includes flip-chip die attach processing (not shown). The method 600 also includes performing a molding process at 610 that forms a package structure that encloses a portion of the one of the conductive leads and engages the obstruction feature or features to oppose movement of the conductive leads relative to the package structure along the first direction X. The method 600 in one example also includes other processes, such as lead trim and form processing to form the conductive leads into a desired shape (e.g., going or J-type lead shapes, not shown). At 612 in FIG. 6, the method 600 further includes package separation, for example, by saw cutting or laser cutting, etc.

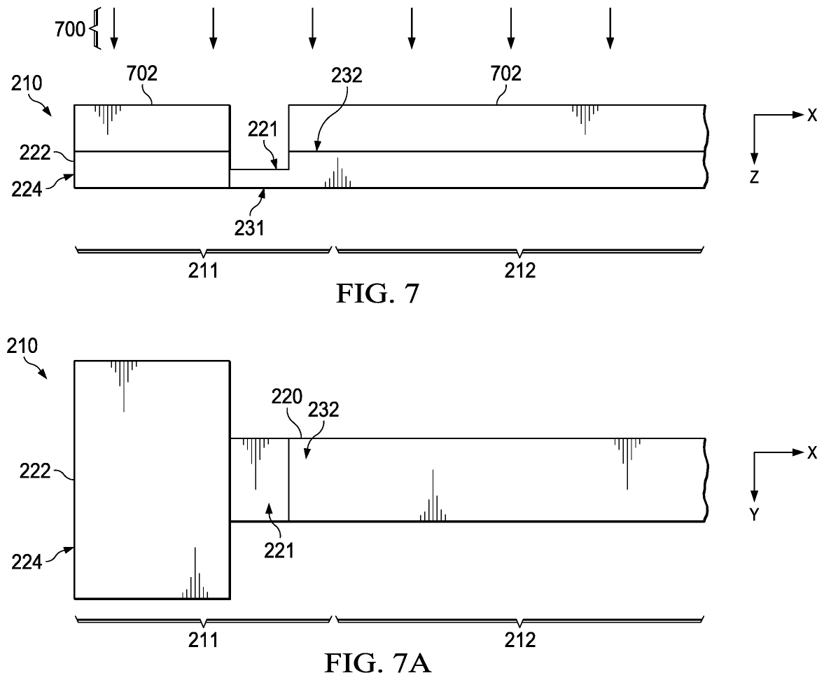

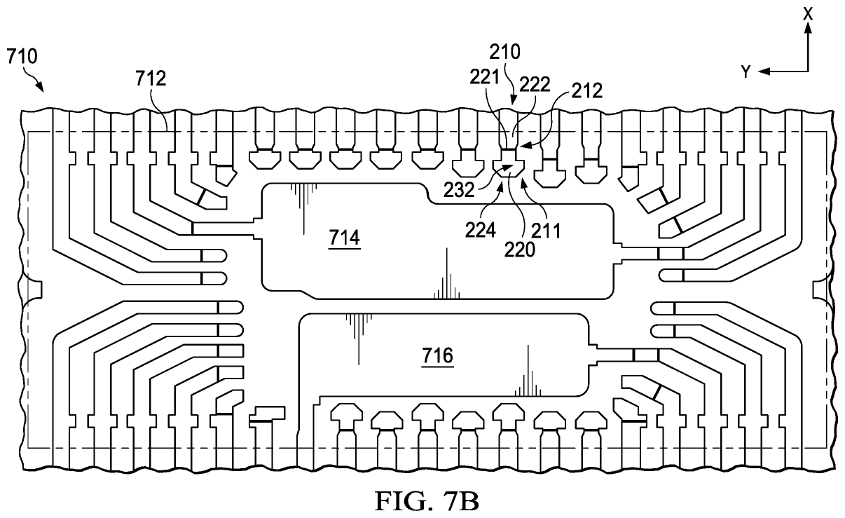

Referring also to FIGS. 7-7B, FIG. 7 shows a partial side elevation view of the conductive lead example of FIGS. 2 and 2A undergoing a chemical etch process to create an indented obstruction feature in a first section of the conductive lead. FIG. 7 shows the conductive lead 210 illustrated and described above in connection with FIGS. 2 and 2A as part of a lead frame panel or strip 701 undergoing a masked chemical etch process 700 using an etch mask 702. The chemical etch process 700 selectively removes exposed copper material from the prospective first section 211 of the conductive lead 210 to form the indent 221 and the sidewall obstruction features thereof. FIG. 7A shows a partial top view of the example conductive lead 210 of the lead frame 701 including the indent 221 in the first section 211. FIG. 7B shows a single device portion of a panel lead frame 701 structure that includes rows and columns of device portions. The illustrated device portion in FIG. 7B includes indents 221 formed in the conductive leads 210, where only one of the example conductive leads 210 includes reference numbers in FIG. 7B for sake of clarity.

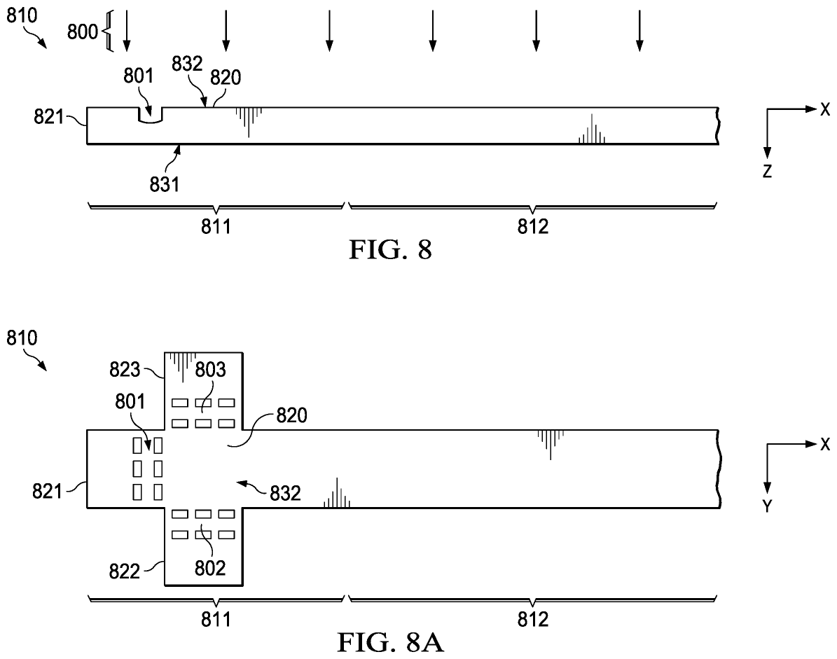

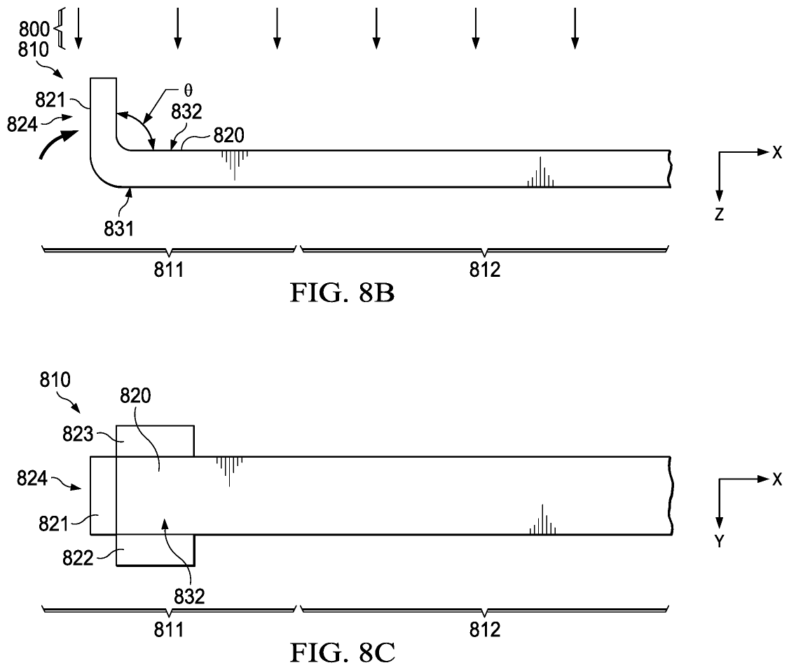

Referring now to FIGS. 8-8C, FIG. 8 shows another conductive lead example 810 undergoing a punch process 800 in a prospective bend area 801 of a first section 811 of the conductive lead 810. The conductive lead 810 has a second portion 812 to be later trimmed and formed (e.g., into a gullwing shape as described above). FIG. 8A shows the conductive lead 810 with three prospective bend areas 801, 802, and 803. The first section 811 of the conductive lead 810 in this example includes a base portion 820 and prospective three obstruction portions 821, 822, and 823. The first section 811 has opposite first and second (e.g., upper and lower) portion sides 831 and 832 that are spaced apart from one another along the third direction Z. FIG. 8B shows the conductive lead 810 undergoing a bending process 800, for example, a die bending process, to form vertical obstruction features by bending the obstruction portions 821, 822, and 823 upward, and FIG. 8C shows the conductive lead 810 with the three obstruction portions 821, 822, and 823 bent aboard to provide vertical obstruction features that extend approximately along the third direction Z. In this example, the second and third obstruction portions 822 and 823 extend out of opposite respective sides of the base portion 820 along the second direction Y. The respective first, second, and third obstruction portions 821, 822, 823 extend outward from the second portion side 832 toward the bottom side of a subsequently molded package structure at a non-zero angle θ of approximately 90° from the second portion side 832.

The described examples improve the ability of a conductive lead to withstand pull out forces and create mechanical resist force against lead pull out. These examples provide improved lead lock features with particular advantages in limited horizontal (e.g., X-Y) spaces such as in fine-pitch electronic device package designs. Various examples can be implemented using chemical etching, stamping and/or bending during lead frame fabrication. The described examples also provide advantages in packaged electronic device designs that include more or larger die pads, for example, to accommodate multi-chip module and/or high voltage isolation products, by using the vertical (e.g., Z-direction) space in situations where die pad and lead spacings in the first and second directions is limited. These examples provide cost-effective solutions for improved pull-out performance compared with narrower mushroom head lead lock designs.

The above examples are merely illustrative of several possible implementations of various aspects of the present disclosure, wherein equivalent alterations and/or modifications will occur to others skilled in the art upon reading and understanding this specification and the annexed drawings. Unless otherwise stated, “about,” “approximately,” or “substantially” preceding a value means +/−10 percent of the stated value. Modifications are possible in the described examples, and other implementations are possible, within the scope of the claims.

What is claimed is:

1. An electronic device, comprising:
a package structure having a first side, a second side, a bottom side, and a top side, the first and second sides spaced apart from one another along a first direction and extending along a second direction that is orthogonal to the first direction, and the bottom and top sides spaced apart from one another along a third direction that is orthogonal to the first and second directions;
a conductive lead having a first section and a second section, the second section extending outside the first side of the package structure, the first section enclosed by the package structure and extending along the first direction into the package structure from the first side to an end, the first section having opposite first and second portion sides and an obstruction feature, the first and second portion sides spaced apart from one another along the third direction, and the obstruction feature extending from one of the first and second portion sides along the third direction and engaging a portion of the package structure to oppose movement of the conductive lead outward from the first side along the first direction.

2. The electronic device of claim 1, wherein the first section has a base portion and an obstruction portion, the base portion extending along the first direction and including the first and second portion sides, and the obstruction portion including the obstruction feature and extending outward at a non-zero angle from the one of the first and second portion sides.

3. The electronic device of claim 2, wherein the obstruction portion extends outward from the second portion side toward the bottom side of the package structure at the non-zero angle from the second portion side.

4. The electronic device of claim 2, wherein the obstruction portion has a U-shape and extends outward from the second portion side toward the bottom side of the package structure at the non-zero angle from the second portion side.

5. The electronic device of claim 4, wherein the non-zero angle is approximately 90 degrees.

6. The electronic device of claim 2, wherein:
the obstruction portion is a first obstruction portion;
the first section has a second obstruction portion; end the first and second obstruction portions extend out of opposite respective sides of the base portion along the second direction.

7. The electronic device of claim 6, wherein:
the first and second obstruction portions extend outward from the second portion side toward the bottom side of the package structure at the non-zero angle from the second portion side; and
the non-zero angle is approximately 45 degrees.

8. The electronic device of claim 2, wherein:
the obstruction portion extends outward from the second portion side toward the bottom side of the package structure at the non-zero angle from the second portion side; and
the obstruction portion extends outward from the second portion side and partially toward the second side of the package structure along the first direction.

9. The electronic device of claim 8, wherein the non-zero angle is approximately 45 degrees.

10. The electronic device of claim 2, wherein:
the obstruction portion is a first obstruction portion;
the first section has a second obstruction portion and a third obstruction portion;
the second and third obstruction portions extend out of opposite respective sides of the base portion along the second direction; and
the first, second, and third obstruction portions extend outward from the second portion side toward the bottom side of the package structure at the non-zero angle from the second portion side.

11. The electronic device of claim 10, wherein the non-zero angle is approximately 45 degrees.

12. The electronic device of claim 1, wherein:
the first section has a base portion with an indent that includes the obstruction feature; and
the indent extends into the one of the first and second portion sides along the third direction.

13. The electronic device of claim 12, wherein the indent extends into the second portion side toward the first portion side of the first section.

14. The electronic device of claim 12, wherein the indent extends laterally through opposite respective sides of the base portion along the second direction.

15. The electronic device of claim 14, wherein the indent extends approximately 50% into the second portion side toward the first portion side of the first section. along the third direction.

16. The electronic device of claim 12, wherein: the indent is a first indent; and the base portion has a second indent that includes another obstruction feature.

17. The electronic device of claim 16, wherein:
the first indent extends into the second portion side toward the first portion side of the first section;
the first indent extends laterally through a first side of the base portion toward an opposite second side of the base portion along the second direction;
the second indent extends into the second portion side toward the first portion side of the first section; and
the second indent extends laterally through the second side of the base portion toward the first side of the base portion along the second direction.

18. A lead frame, comprising:
a conductive lead having a first section and a second section, the first section extending along a first direction in a plane of the first direction and an orthogonal second direction and having opposite first and second portion sides and an obstruction feature, the first and second portion sides spaced apart from one another along a third direction that is orthogonal to the first and second directions, and the obstruction feature extending from one of the first and second portion sides along the third direction and configured to engage a portion of a package structure to oppose movement of the conductive lead relative to the package structure along the first direction.

19. A method of fabricating an electronic device, the method comprising:
forming a lead frame with conductive leads in a plane of orthogonal first and second directions;
forming an indent or raised feature extending from a side of one of the conductive leads to provide an obstruction feature;
attaching a die to the lead frame;
electrically coupling conductive terminals of the die to respective ones of the conductive leads; and
performing a molding process that forms a package structure that encloses a portion of the one of the conductive leads and engages the obstruction feature to oppose movement of the one of the conductive leads relative to the package structure along the first direction.
